(19) United States
(12) Patent Application Publication
(10) Pub. No.: US 2022/0103407 A1
(43) Pub. Date: Mar. 31, 2022

(54) FSK RADIO-FREQUENCY DEMODULATORS

(71) Applicant: Nordic Semiconductor ASA, Trondheim (NO)

(72) Inventors: Philip CORBISHLEY, Trondheim (NO); Sverre WICHLUND, Trondheim (NO); Ralf HEKMANN, Trondheim (NO); Eivind Sjøgren OLSEN, Trondheim (NO)

(73) Assignee: Nordic Semiconductor ASA, Trondheim (NO)

(21) Appl. No.: 17/448,675

(22) Filed: Sep. 23, 2021

(30) Foreign Application Priority Data
Sep. 25, 2020 (GB) 2015234.4

(51) Int. Cl. H04L 27/14

(52) U.S. Cl. CPC H04L 27/14; H04W 4/80

(57) ABSTRACT

A demodulator for a digital radio receiver comprises a frequency discriminator and a Viterbi decoder. The frequency discriminator receives a series digital signal samples representative of an FSK-modulated signal and performs frequency discrimination on the digital signal samples to generate a series of frequency samples. Each frequency sample represents an instantaneous frequency of the signal in a respective frequency-sample period. There are an integer oversampling factor, N>1, of frequency-sample periods in each symbol period. The Viterbi decoder receives the series of frequency samples, determines branch metrics for each symbol period by determining distances between a vector of N successive frequency samples and each of a plurality of reference waveform vectors, each comprising N elements. It use the branch metrics in a Viterbi process to output demodulated symbol values corresponding to a maximum-likelihood decoding of the FSK-modulated signal.

### CROSS-REFERENCE TO RELATED APPLICATION

This application claims the benefit of Great Britain Application No. GB2015234.4, filed Sep. 25, 2020. The Great Britain application is incorporated herein in its entirety.

### BACKGROUND OF THE INVENTION

This invention relates to demodulators for digital radio receivers and to methods of demodulating FSK-modulated signals.

It is known to transmit digital data using frequency-shift keying (FSK) in which the frequency of a radio carrier is modulated between two or more frequencies in dependency on the symbols to be transmitted. Binary FSK (BFSK) uses two levels to transmit binary data one bit at a time, while multi-level FSK uses more than two frequencies in order to transmit a multi-bit symbol in each symbol period.

Radio receivers perform demodulation in order to recover the original data stream from the radio signal. Coherent demodulators lock on to the phase of the carrier wave, e.g. using a phase-locked loop. This can give high demodulation accuracy but the required carrier recovery circuitry is complex. Therefore many simpler receivers perform non-coherent demodulation instead, in which the signal is demodulated without first recovering the carrier phase.

One known approach for non-coherent demodulation of an FSK signal is to use a frequency discriminator to determine an instantaneous frequency of the signal at each symbol period, and to map this to the corresponding symbol. Frequency discriminators may be analogue or digital devices. They output a signal that is proportional to the instantaneous frequency of the incoming signal, which they typically generate by multiplying the signal with a delayed version of itself and then low-pass filtering the result.

However, such an approach has relatively poor sensitivity, especially when the transmitted FSK signal has been shaped to reduce sideband power—e.g. using a Gaussian filter—which increases intersymbol interference.

The present invention seeks to provide a demodulator for demodulating FSK-modulated signals with better sensitivity.

### SUMMARY OF THE INVENTION

From a first aspect, the invention provides a demodulator for a digital radio receiver, the demodulator comprising:
a frequency discriminator; and
a Viterbi decoder,

wherein the frequency discriminator comprises:
an input for receiving a series digital signal samples representative of a frequency-shift-key (FSK)-modulated signal; and
digital logic for performing frequency discrimination on the digital signal samples to generate a series of frequency samples, wherein each frequency sample is representative of an instantaneous frequency of the FSK-modulated signal in a respective frequency-sample period, and wherein there are an integer oversampling factor, N, greater than one, of frequency-sample periods in each symbol period of the FSK-modulated signal, and
   wherein the Viterbi decoder is arranged to:
receive the series of frequency samples from the frequency discriminator;
determine a plurality of branch metrics for each symbol period of the FSK-modulated signal by determining a plurality of distances between a vector of N successive received frequency samples and each of a plurality of reference waveform vectors, wherein each reference waveform vector comprises N elements;
use the determined branch metrics in a Viterbi process to determine a maximum-likelihood decoding of the FSK-modulated signal; and
output a series of demodulated symbol values corresponding to the maximum-likelihood decoding of the FSK-modulated signal.

From a second aspect, the invention provides a method for demodulating a frequency-shift-key (FSK)-modulated signal, the method comprising:
receiving a series digital signal samples representative of the frequency-shift-key (FSK)-modulated signal;
performing frequency discrimination on the digital signal samples to generate a series of frequency samples, wherein each frequency sample is representative of an instantaneous frequency of the FSK-modulated signal in a respective frequency-sample period, and wherein there are an integer oversampling factor, N, greater than one, of frequency-sample periods in each symbol period of the FSK-modulated signal;
determining a plurality of branch metrics for each symbol period of the FSK-modulated signal by determining a plurality of distances between a vector of N successive received frequency samples and each of a plurality of reference waveform vectors, wherein each reference waveform vector comprises N elements;
using the determined branch metrics in a Viterbi process to determine a maximum-likelihood decoding of the FSK-modulated signal; and
outputting a series of demodulated symbol values corresponding to the maximum-likelihood decoding of the FSK-modulated signal.

Thus it will be seen that, in accordance with the invention, the output of a frequency discriminator is oversampled to produce N≥2 frequency samples per symbol period, and these N frequency samples are processed in a Viterbi decoder for each symbol, using a plurality of reference waveform vectors, to demodulate the FSK-modulated signal.

Viterbi decoders are more typically used to deconvolve convolution-encoded data, but the Viterbi decoder is here used as a symbol detector in order to improve the demodulation sensitivity by exploiting the likelihoods of particular state transitions between successive symbol periods at each iteration.

The plurality of multi-element reference waveform vectors enable preceding symbols to influence the demodulation of a current symbol. By oversampling the frequency discriminator output and determining the Viterbi branch metrics based on distances to multi-element waveform vectors that have multiple samples for each symbol period, rather than based on a single frequency sample per symbol, the reference waveforms may take account of any intersymbol smearing inherent in the operation of a transmitter modulator, so improving the sensitivity of the receiver. This sensitivity improvement can be particularly significant when the FSK signal is shaped, e.g. with a Gaussian filter, since it allows the reference waveform vectors to take account of the filter shaping. This can help to mitigate the intersymbol interference (ISI) that occurs when using a filter.

From a third aspect, the invention provides a digital radio receiver comprising a demodulator as disclosed herein.

The digital radio receiver may comprise an antenna for receiving the frequency-shift-key (FSK)-modulated signal as a radio signal. It may comprise an amplifier for amplifying the received radio-frequency (RF) FSK-modulated signal. It may comprise one or more analogue and/or digital mixers for downmixing the RF signal, e.g. to an intermediate frequency and/or to baseband. The mixer may be a quadrature mixer. The radio receiver may comprise one or more analogue and/or digital filters. It may comprise an analogue-to-digital converter (ADC) for generating the series of digital signal samples, which may be complex sample values. The digital radio receiver may comprise dedicated digital logic and/or a processor for further processing the series of demodulated symbol values.

The FSK-modulated signal may be a non-filtered signal, but in preferred embodiments it is a shape filtered signal. It may be a Gaussian filtered signal—i.e. a GFSK-modulated signal. The signal may have been filtered by a filter having a 3 dB bandwidth-symbol time product, BT, of 0.5 or less. In some embodiments, the filter has a BT of around 0.25 or less. In some embodiments, the filter has a BT between 0.2 and 0.3, e.g. between 0.24 and 0.26, such as 0.25. The sensitivity of embodiments of demodulator are well-suited to demodulating such wide-filtered signals with low error rate. The signal may be a minimum-shift-key (MSK)-modulated signal, e.g. a GMSK-modulated signal.

From a fourth aspect, the invention provides a digital radio system comprising a digital radio receiver as disclosed herein, and further comprising a digital radio transmitter. The digital radio receiver may be a first apparatus, and the digital radio transmitter may be a second apparatus, distinct from, and potentially remote, from the first apparatus. The radio transmitter may be configured to transmit the frequency-shift-key (FSK)-modulated signal. It may comprise an antenna for transmitting the signal as a radio signal. It may comprise a modulator for modulating the signal. It may comprise a filter for shape-filtering the signal.

The reference waveform vectors may comprise elements (i.e. values) that correspond to the type of signal the demodulator is arranged to receive—e.g. representing GFSK-modulated waveforms.

The FSK-modulated signal may be a binary-modulated signal—i.e. BFSK (with or without Gaussian filtering). The symbol periods will then be bit periods. This can advantageously enable an efficient demodulator design by enabling the number of states in the Viterbi decoder to be lower than when it is designed for demodulating a multi-level signal (i.e. an MFSK signal).

The Viterbi decoder may have M^{k} states, where M is the integer size of the symbol alphabet and/or the number of FSK frequencies (e.g. M=2 for binary modulation), and where k is an integer, preferably equal to two or more. Each state may correspond to a different combination of k symbols modulated by the transmitter modulator immediately preceding the current symbol. The value of k may be chosen, in some embodiments, based on the symbol-span of a shaping filter for the signal—i.e. based on how many adjacent symbol periods are influenced by each symbol.

The plurality of reference waveform vectors may comprise, or consist of, M^{k+1} vectors. These may correspond to the M^{k} combinations for the k preceding symbols, multiplied by the M possibilities for the current symbol.

In some embodiments, the integer value k is equal to two. The Viterbi decoder can thus model the state of a transmitter modulator at each symbol period based on what preceding pairs of symbols were transmitted. This results in a particularly efficient implementation. However, k could equal three or more.

In some embodiments, the signal is binary-FSK modulated and the integer value k is equal to two. The Viterbi decoder may then be a four-state decoder (i.e. with a state for each possible pair of preceding bits: “00”, “01”, “10”, “11”). This is expected to provide particularly good sensitivity when demodulating a signal shaped with a shaping filter having a pulse width spanning roughly two bits, such as a Gaussian filter with a BT of around 0.25. Such a Viterbi decoder calculates a new set of branch metrics each bit period. The plurality of reference waveform vectors may then consist of eight reference waveform vectors, corresponding to two possible next states (a “0” or “1” current bit) for each of the four states in a trellis of the Viterbi process implemented by the Viterbi decoder. By using only four states, preferred embodiments have low complexity, which can lead to low power consumption and a small physical chip area when the decoder is implemented in an integrated-circuit chip.

The oversampling factor N may take any suitable value. A value less than ten—e.g. four or eight—may provide a good balance between sensitivity and implementation complexity, at least in some embodiments.

The elements of the reference waveform vectors may be hardwired into the Viterbi decoder or they may be stored as data in a memory—e.g. in a register or random access memory (RAM).

The Viterbi decoder may be configured to use the branch metrics to calculate a set of path metrics. It may use the path metrics to perform a trace-back operation for demodulating the FSK-modulated signal. The series of demodulated symbol values preferably includes every symbol contained in the FSK-modulated signal.

The Viterbi decoder may be implemented at least partly in software executing on a processor. However, in preferred embodiments, it is implemented entirely as a dedicated hardwired circuit—i.e. using hardware logic gates. This can result in lower power and/or better performance than a software-based implementation, and can free up a processor for other tasks.

The frequency discriminator may perform a digital multiplication operation on the signal samples. It may multiply the signal samples with a delayed (i.e. sample-wise offset) copy of the signal samples. The frequency discriminator may be a dedicated hardwired circuit—i.e. not implemented in software. It may operate on complex-valued samples.

The demodulator is preferably a non-coherent demodulator.

The demodulator and/or digital radio receiver may be implemented as an integrated-circuit chip. It may be part of a radio-on-a-chip.

In some embodiments, the demodulator and/or digital radio receiver are configured for demodulating radio signals in a 2.4 GHz band—e.g. having a carrier frequency between 2.4 and 2.5 GHz. They may be configured for demodulating signals modulated according to any (present or future) Bluetooth™ specification—e.g. for demodulating Bluetooth™ Low Energy signals. They may be configured for demodulating signal modulated on a channel having a width of 4 MHz and/or having a data rate exceeding 2 Mbps, such as 4 Mbps.

Features of any aspect or embodiment described herein may, wherever appropriate, be applied to any other aspect or embodiment described herein. Where reference is made to different embodiments or sets of embodiments, it should be understood that these are not necessarily distinct but may overlap.

### BRIEF DESCRIPTION OF THE DRAWINGS

Certain preferred embodiments of the invention will now be described, by way of example only, with reference to the accompanying drawings, in which:

FIG. 1 is a schematic drawing of a radio communication system including a radio receiver device embodying the invention;

FIG. 2 is a schematic drawing of receiver circuitry in the radio receiver device; and

FIG. 3 is a schematic drawing of a demodulator in the receiver circuitry.

### DETAILED DESCRIPTION

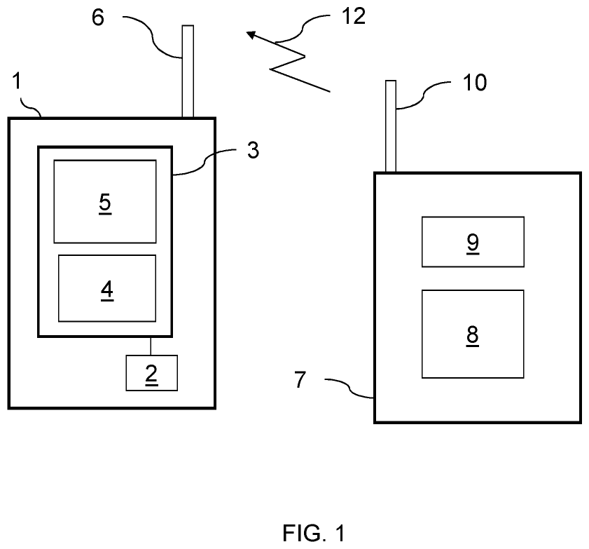

FIG. 1 shows an exemplary wearable wireless heart-rate monitor 1 which is in communication with a mobile telephone 7. The heart-rate monitor 1 implements the present invention.

The wireless heart-rate monitor 1 has a heart-rate sensor 2 which is connected to a radio-on-a-chip 3. The radio-on-a-chip 3 comprises a microcontroller unit (MCU) 4, e.g. based around an ARM™ Cortex M-series processor, and a radio transceiver 5. The radio-on-a-chip 3 and/or MCU 4 may include other components, such as volatile and non-volatile memory, other peripherals, etc. The heart-rate monitor 1 has a radio antenna 6, which may be integrated on the chip 3 or external to it, as well as other standard components, such as a battery, a display screen, buttons, off-chip memory, amplifier circuitry, discrete electronics components, etc. The antenna 6 is suitable for transmitting and receiving short-range radio communications—e.g. according to a 2.4 GHz protocol such as Bluetooth Low Energy™ (BLE).

The mobile telephone 7 has a microcontroller unit (MCU) 8 and radio transceiver circuitry 9. These may be integrated on a common chip, or be provided as separate integrated circuit chips. The radio transceiver 9 is connected to an antenna 10 that is suitable exchanging short-range radio communications with wireless personal-area-network devices—e.g. according to a 2.4 GHz protocol such as Bluetooth Low Energy™. The telephone 7 may include further components, such as further microprocessors, other radio chips, a display screen, a battery, etc. It may run an operating system and software applications.

In use, the wireless heart-rate monitor 1 receives periodic heart-rate readings for a human user from the heart-rate sensor 2. The MCU 4 processes the readings into a suitable format for transmission, and controls the radio transceiver 5 to transmit the data to the mobile telephone 7 by a short-range 2.4 GHz radio message. The heart-rate monitor 1 receives a radio acknowledgement message 12 from the mobile telephone 7, generated by the transceiver 9 and transmitter through the antenna 10 of the telephone 7. The radio message 12 is received at the antenna 6 of the heart-rate monitor 1 and decoded by its radio transceiver 5.

These radio messages may be exchanged using a protocol complying with an existing or future Bluetooth™ standard, which may be a Bluetooth Low Energy™ protocol. In some embodiments, it uses such a protocol in which data is transmitted in a 4 MHz channel, potentially at a data rate exceeding 2 Mbps, such as 4 Mbps. At such high data rates, receiver sensitivity becomes particularly important in order to avoid decoding errors.

In one example embodiment, radio messages 12 received by the radio transceiver 5 contain encoded data that is modulated on a radio-frequency carrier at around 2.4 GHz using two-level Gaussian frequency-shift keying (GFSK) with a modulation index, h, of 0.5, and with a Gaussian pulse-shaping filter bandwidth-time product, BT, of 0.25 (where B is the −3 dB bandwidth of the filter, and T is the bit duration). Such a filter helps reduce sideband power but creates significant “smear” across bits, leading to high intersymbol interference (ISI), placing additional requirements on receiver sensitivity.

The radio transceiver 5 performs non-coherent detection of the GFSK signal 12. It uses a frequency discriminator and a Viterbi decoder as a demodulator (i.e. a bit detector), in order to detect a bitstream from the received signal 12, which it can then pass to the microcontroller 4 for further processing. It is important to note that the Viterbi decoder is not here being used to perform a deconvolution decoding of a convolution-encoded data stream, but rather to generate a raw demodulated bitstream from the received RF signal.

In some embodiments, the bitstream may potentially include convolution-encoded data, but this is not essential, and it is also not of relevance here. The radio-on-a-chip 3 may optionally include logic for performing a subsequent deconvolution operation on the detected bitstream, to decode convolution-encoded data, but that would be separate from this Viterbi decoder 27—e.g. being provided by software executing in the microcontroller 4 or by a further hardware Viterbi decoder circuit (not shown) in the transceiver 5. In some embodiments, the first Viterbi decoder 27 may be configured to perform a soft-output Viterbi algorithm in order to output soft-decision bit values (e.g. a value between 0 and 1), rather than hard-decision bits. This may improve the performance of any subsequent decoding, e.g. by a further Viterbi decoder.

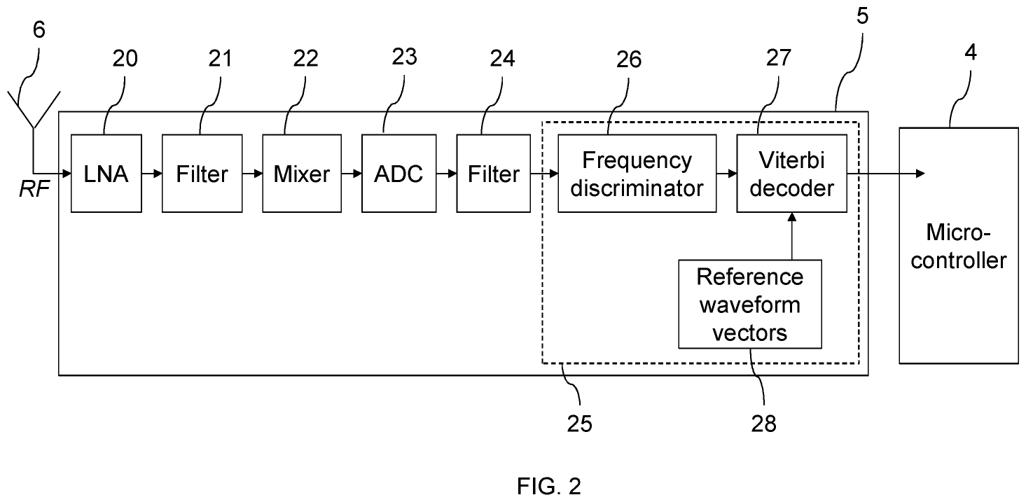

FIG. 2 provides more detail of the receive-side circuitry in the radio transceiver 5 of the heart-rate monitor 1.

The 2.4 GHz radio-frequency electrical signal from the antenna 6 is received by a low-noise amplifier 20. The amplified analogue signal is then filtered by an analogue bandpass filter 21 and passed to a quadrature mixer 22 which down-mixes the signal to a lower intermediate frequency (IF). The down-mixed signal is then sampled by an analogue-to-digital converter (ADC) 23. Further filtering may be applied by one or more digital filters 24. The filtered samples are then passed to a demodulator (i.e. a bit detector) 25, which includes a frequency discriminator 26, a Viterbi decoder 27, and a store of reference waveform vectors 28.

The frequency discriminator 26 acts on the quadrature samples to generate a stream of values that are proportional to the frequency of the received signal. It may do this in any appropriate way. For example, it may implement a digital delay-and-multiply process followed by a low-pass filter, so as to generate a signal that is proportional to the frequency of the sampled down-mixed signal. The frequency discriminator 26 outputs a stream of digital frequency samples at an oversampling rate N—i.e. such that there are N samples for each received bit. N may equal four or eight, or any other value greater than one.

The frequency samples are passed to a soft-decision Viterbi decoder 27. The Viterbi decoder 27 iterates at each bit period.

Because the pulse width of a Gaussian pulse shaping filter with BT=0.25 spans approximately two bits, the GFSK modulator in the transmitter 8 can be viewed as a state machine having four states, depending on whether the preceding two bits were “00”, “01”, “10” or “11”. Each bit received by the transceiver 5 can therefore be considered to be a function of i) the modulator state (i.e. what the preceding two bits were), ii) the current modulator input, and iii) the channel. The Viterbi decoder 27 therefore has four states, corresponding to the four possible states of the modulator. Simulations have confirmed the effectiveness of this approach.

If a different transmission shaping filter, spanning more bits, is used, the Viterbi decoder could have correspondingly more states—e.g. having eight or sixteen states if the filter spans three or four bits.

Within the Viterbi decoder 27, for each received FSK-encoded bit, a vector of the N frequency samples received from the frequency discriminator 26 for the current bit period is compared with each of eight reference waveform vectors 28, (wref₀,wref₁, . . . , wref₇) each having N elements, by calculating a respective squared Euclidean distance between the frequency-sample vector and each reference waveform vector 28.

In this embodiments there are eight reference waveform vectors 28 because the trellis has four states (corresponding to the four modelled states of the GFSK modulator, depending on whether the preceding two bits were “00”, “01”, “10” or “11”), and because each state has two possible next states, “0” or “1”, amounting to eight branches in total. Each eight reference waveform vector is pre-calculated to represent the output from a GFSK modulator of BT=0.25 given that the Gaussian filter contains one the preceding bit pairs “00”, “01”, “10” or “11” with the next message input bit to the modulator being either “0” or “1”.

These comparisons produce a set of eight branch-metric values, bmⱼ, for j={0, . . . , 7}, as follows:

$$b {m}_{j} = {\sum }_{i = 0}^{N - 1} {( {wref}_{j , i} - {fm}_{i} )}^{2}$$

where fmᵢ is the received frequency sample i indexed over the current bit period (0≤i<N), and wref_{j,i} is the i^{th} reference sample from the reference waveform j.

The 8× N reference waveform vector elements 28 may be stored by being hardwired into the digital logic of the hardware Virterbi decoder 27 circuitry (e.g. as corresponding shift and accumulate operations), or they may be retrieved by the Viterbi decoder 27 from volatile or non-volatile registers or from a random access memory (RAM) as inputs to one or more multipliers.

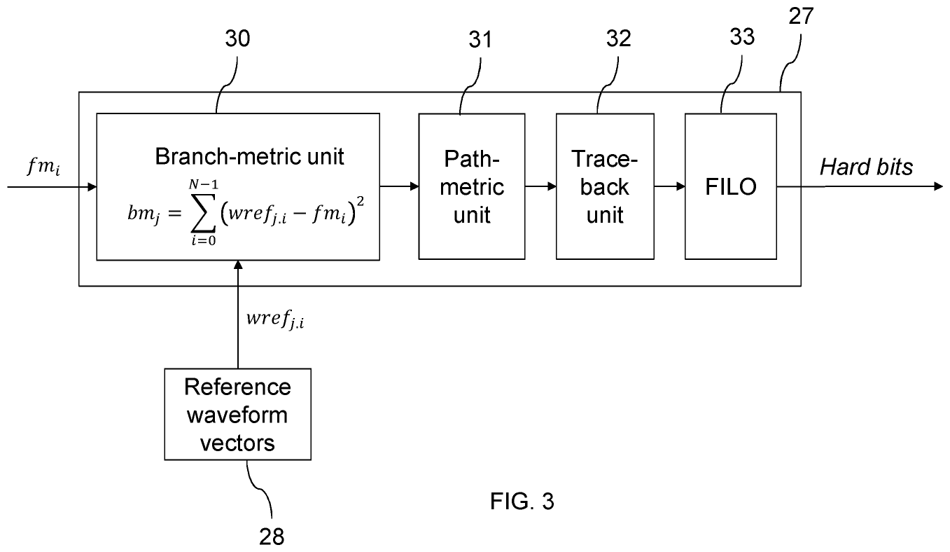

FIG. 3 shows the Viterbi decoder 27 part of the demodulator 25 in more detail. For reasons of speed, power and silicon area, the demodulator 25 is here implemented in hardware (i.e. using dedicated logic gates) on the chip 3. However, in other embodiments, some or all of the demodulator operations could potentially be implemented by software executing on a processor.

A branch-metric unit 30 receives N samples for each bit, from the frequency discriminator 26, and calculates a set of branch-metric values, bmⱼ, for each bit pair, one bit at a time, as described above. These branch metrics are then input to a path-metric unit 31 which uses them to calculate new path metrics at each bit period, based on the preceding path metrics and the new branch metrics, according to the Viterbi algorithm. It compares the path metrics and selects the most likely paths, using the Viterbi algorithm.

In some embodiments, decision bits from the path-metric unit 31, representing survivor paths, are stored in sequence in the trace-back unit 32, and used for trace back after the maximum-likelihood survivor path has been determined. The path metrics may be accumulated over any appropriate number of bits. They could potentially be accumulated over an entire message, but it may be less than this—e.g. for reasons of speed or resource efficiency. Some embodiments accumulate over 12 bits, which simulations have suggested can still provide good performance. A first-in-last-out (FILO) buffer 33 reverses the path order, so that the decoder 27 outputs a chronological stream of hard-decision bit values, representing the data bits detected from the received signal 12.

In other embodiments, the Viterbi decoder may use a Register Exchange (RE) architecture, instead of a trace-back unit 32, which may provide a more efficient implementation, given the relatively small size of this Viterbi decoder.

The output bits may be further processed in hardware and/or software as appropriate—e.g. to check that the mobile telephone 7 correctly received the transmitted heart-rate data, in this example.

In some variants, the Viterbi decoder may output soft-bits, instead of or as well as hard-bits. This may facilitate further decoding by a downstream decoder, e.g. in cases where the received data is convolution-encoded and requires further processing by a second Viterbi decoder.

The radio transceiver 5 may include circuitry for performing frame-level and bit-level timing synchronisation. It may include circuitry for automatic gain control, and for other conventional operations related to receiving and decoding digital radio signals. The radio transceiver 5 also includes conventional transmitter circuitry for transmitting radio messages.

This receiver architecture has been found to offer high sensitivity, making it well suited for receiving signals modulated using a relatively wide Gaussian filter (e.g. spanning two or more bits), which results in high levels of inter-symbol interference (ISI).

Although embodiments have been described for demodulating binary FSK signals, it will be appreciated that the same principles can also be applied for demodulating higher-level FSK modulated signals, such as four-level FSK (4FSK) or higher, in other embodiments. In this case, the number of states of the Viterbi decoder will increase, as will the number of reference waveform vectors.

While the receiver design is well suited to demodulating signals transmitted with Gaussian shaping (which helps to reduce sideband power, thereby reducing interference between adjacent channels), the use of GFSK is not essential, and some embodiments may be used to receive differently-shaped BFSK signals, or non-filtered BFSK-modulated signals, by using appropriate reference waveform vectors 28 in the Viterbi decoder 27.

It will be appreciated by those skilled in the art that the invention has been illustrated by describing one or more specific embodiments thereof, but is not limited to these embodiments; many variations and modifications are possible, within the scope of the accompanying claims.

1. A demodulator for a digital radio receiver, the demodulator comprising:
a frequency discriminator; and
a Viterbi decoder,
wherein the frequency discriminator comprises:
an input for receiving a series digital signal samples representative of a frequency-shift-key (FSK)-modulated signal; and
digital logic for performing frequency discrimination on the digital signal samples to generate a series of frequency samples, wherein each frequency sample is representative of an instantaneous frequency of the FSK-modulated signal in a respective frequency-sample period, and wherein there are an integer oversampling factor, N, greater than one, of frequency-sample periods in each symbol period of the FSK-modulated signal, and
wherein the Viterbi decoder is arranged to:
receive the series of frequency samples from the frequency discriminator;
determine a plurality of branch metrics for each symbol period of the FSK-modulated signal by determining a plurality of distances between a vector of N successive received frequency samples and each of a plurality of reference waveform vectors, wherein each reference waveform vector comprises N elements;
use the determined branch metrics in a Viterbi process to determine a maximum-likelihood decoding of the FSK-modulated signal; and
output a series of demodulated symbol values corresponding to the maximum-likelihood decoding of the FSK-modulated signal.

2. The demodulator of claim 1, configured to demodulate a Gaussian-filtered FSK-modulated signal and wherein the reference waveform vectors comprise elements that correspond to Gaussian-filtered waveforms.

3. The demodulator of claim 1, configured to demodulate an FSK-modulated signal modulated on M frequencies, wherein M is equal to two or more, and wherein the Viterbi decoder has M^{k} states, wherein k is an integer equal to two or more.

4. The demodulator of claim 1, configured to demodulate a binary FSK-modulated signal, filtered with a Gaussian filter having a bandwidth-symbol time product between 0.2 and 0.3, and wherein the Viterbi decoder has four states.

5. The demodulator of claim 1, wherein the plurality of reference waveform vectors consists of eight reference waveform vectors.

6. The demodulator of claim 1, wherein the oversampling factor N is less than ten.

7. The demodulator of claim 1, wherein the frequency discriminator is configured to multiply the signal samples with a delayed copy of the signal samples.

8. The demodulator of claim 1, wherein the Viterbi decoder is implemented as a dedicated hardwired circuit.

9. The demodulator of claim 1, implemented on an integrated-circuit chip.

10. A digital radio receiver comprising a demodulator as claimed in claim 1.

11. The digital radio receiver of claim 10, comprising an antenna for receiving the frequency-shift-key (FSK)-modulated signal as a radio signal, and comprising dedicated digital logic or a processor for further processing the series of demodulated symbol values.

12. The digital radio receiver of claim 10, configured for receiving and demodulating radio signals having a carrier frequency between 2.4 and 2.5 GHz.

13. The digital radio receiver of claim 10, configured for receiving and demodulating radio signals modulated according to a Bluetooth™ specification.

14. The digital radio receiver of claim 10, configured for receiving and demodulating radio signals that are modulated on a channel having a width of 4 MHz and that have a data rate exceeding 2 Mbps.

15. A method for demodulating a frequency-shift-key (FSK)-modulated signal, the method comprising:
receiving a series digital signal samples representative of the frequency-shift-key (FSK)-modulated signal;
performing frequency discrimination on the digital signal samples to generate a series of frequency samples, wherein each frequency sample is representative of an instantaneous frequency of the FSK-modulated signal in a respective frequency-sample period, and wherein there are an integer oversampling factor, N, greater than one, of frequency-sample periods in each symbol period of the FSK-modulated signal;
determining a plurality of branch metrics for each symbol period of the FSK-modulated signal by determining a plurality of distances between a vector of N successive received frequency samples and each of a plurality of reference waveform vectors, wherein each reference waveform vector comprises N elements;
using the determined branch metrics in a Viterbi process to determine a maximum-likelihood decoding of the FSK-modulated signal; and
outputting a series of demodulated symbol values corresponding to the maximum-likelihood decoding of the FSK-modulated signal.

16. The method of claim 15, wherein the FSK-modulated signal is a Gaussian-filtered FSK-modulated signal, and wherein the reference waveform vectors comprise elements that correspond to Gaussian-filtered waveforms.

17. The method of claim 15, wherein the FSK-modulated signal is modulated on M frequencies, wherein M is equal to two or more, and wherein the Viterbi decoder has M^{k} states, wherein k is an integer equal to two or more.

18. The method of claim 15, wherein the FSK-modulated signal is a binary FSK-modulated signal, filtered with a Gaussian filter having a bandwidth-symbol time product between 0.2 and 0.3, and wherein the Viterbi decoder has four states.

19. The method of claim 15, wherein the FSK-modulated signal has a carrier frequency between 2.4 and 2.5 GHz.

20. The method of claim 15, wherein the FSK-modulated signal has a data rate exceeding 2 Mbps and is modulated on a channel that has a width of 4 MHz.
